(19) United States
(12) Patent Application Publication
(10) Pub. No.: US 2025/0221273 A1
(43) Pub. Date: Jul. 3, 2025

(54) DISPLAY DEVICE

(71) Applicant: LG Display Co., Ltd., Seoul (KR)

(72) Inventors: Se Hong PARK, Paju-si (KR); Seo Hyun NAM, Paju-si (KR); In Goo LEE, Paju-si (KR); Young Nam LIM, Paju-si (KR); Dae Heung LEE, Paju-si (KR); Hyeon Hye YU, Paju-si (KR)

(73) Assignee: LG Display Co., Ltd., Seoul (KR)

(21) Appl. No.: 18/916,023

(22) Filed: Oct. 15, 2024

(30) Foreign Application Priority Data
Dec. 29, 2023 (KR) 10-2023-0197790

(51) Int. Cl. H10K 59/80; H10K 102/00

(52) U.S. Cl. CPC H10K 59/877; H10K 2102/331

(57) ABSTRACT

A display device includes a base substrate including a pixel area and a non-pixel area; an overcoat layer on the base substrate, the overcoat layer including a groove at an area corresponding to the non-pixel area; a first electrode on the overcoat layer at an area corresponding to the pixel area; an emission layer in the groove and on the first electrode; and a second electrode on the emission layer, the second electrode at an area corresponding to the pixel area and in the groove.

This application claims the priority benefit of Republic of Korea Patent Application No. 10-2023-0197790, filed on Dec. 29, 2023, in the Korean Intellectual Property Office, which is incorporated herein by reference for all purposes as if fully set forth herein.

### BACKGROUND

### Technical Field

The present disclosure relates to electronic devices with displays, and more particularly, to display devices with improved light extraction efficiency.

### Discussion of the Related Art

As the information-oriented society has been developed, display technology have developed rapidly to meet various needs for visually expressing information, data, applications, and the like. Indeed, various types of display devices with excellent performance, such as thin in profile, light weight, low power consumption, and the like have been developed.

As such display devices, liquid crystal display (LCD) devices, plasma display panel (PDP) devices, quantum dot (QD) display devices, organic light emitting diode (OLED) display devices, field emission display (FED) devices.

Among these display devices, organic light emitting display devices can provide advantages of light weight and thin package because a separate light source, such as a backlight, cannot be required, and low power consumption based on low voltage driving.

In the case of organic light emitting display devices, light emitted from an emission layer can exit the display device by passing through various elements and/or layers; however, a significant portion of the emitted light can be lost while exiting the display device. An amount of light reaching the outside may be only about 20% of the light emitted from the emission layer.

An amount of light emitted from an emission layer can increase in proportion to an amount of current applied thereto. To improve the luminance of a display device, a more amount of current is needed to be provided to the display device, and this leads to increased power consumption. It is therefore desirable to improve light extraction efficiency.

### SUMMARY

To address these issues, the inventors of the present disclosure have developed a technology of applying a micro lens array (MLA) structure to an overcoat layer of a display device.

However, in an example where a micro lens array is applied to a display device, a phase of incident light coming from the outside can be shifted more than a preset range due to a curvature of the micro lens array. In this case, when passing through a base substrate, incident light and exit light may travel with a same phase, and the incident light cannot be effectively shielded. Thus, a ratio of reflected light to the incident light and/or the exit light can be increased, and a black image defect in which black is not presented at an intended brightness may occur. As a result, black visibility may be degraded in a display device with such a micro lens array.

To address these issues, the inventors of the present disclosure have invented display devices with improved light efficiency without employing a micro lens array (MLA) structure by disposing a light scattering portion for scattering wave guide mode light in an overcoat layer.

Accordingly, embodiments of the present disclosure are directed to a display device that substantially obviates one or more of the problems due to limitations and disadvantages of the related art.

An aspect of the present disclosure is to provide a display device capable of improving light efficiency without employing a micro lens array (MLA) structure by including a light scattering portion for scattering wave guide mode light so that the scattered light can exit the display device in various paths.

An aspect of the present disclosure is to provide a display device capable of improving light efficiency without employing a micro lens array (MLA) structure, reducing a ratio of reflected light to light emitted from a light source, and correcting a black image defect.

An aspect of the present disclosure is to provide a display device with improved front, left, and right viewing angles by including a light scattering portion for scattering light in a wave guide mode in which the light is totally reflected at an interface between an emission layer and an insulating layer, such as an overcoat layer, or the like, and then travels sidewards (e.g., leftwards or rightwards) (which may referred to as “wave guide mode light”), and thereby, causing the scattered light to travel in various optical paths.

An aspect of the present disclosure is to provide a display device with improved luminance by disposing a second electrode, which is used as a reflective electrode, in a groove of an overcoat layer, and causing wave guide mode light, which is totally reflected at an interface between an emission layer and an insulating layer, such as an overcoat layer, or the like, and then travels sidewards (e.g., leftwards or rightwards), to be reflected again by the second electrode and then to travel to the outside.

An aspect of the present disclosure is to provide a display device capable of being operated with low power as light extraction efficiency is improved by a light scattering portion and a second electrode disposed in an overcoat layer.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described, a display device may comprise a base substrate including a pixel area and a non-pixel area; an overcoat layer on the base substrate, the overcoat layer including a groove at an area corresponding to the non-pixel area; a first electrode on the overcoat layer at an area corresponding to the pixel area; an emission layer in the groove and on the first electrode; and a second electrode on the emission layer, the second electrode at an area corresponding to the pixel area and in the groove.

In another aspect, a display device may comprise a base substrate including a pixel area and a non-pixel area; an overcoat layer on the base substrate, the overcoat layer including a recessed space in an area corresponding to the pixel area or the non-pixel area, wherein a light scattering portion is in the recessed space; a first electrode on the overcoat layer in an area corresponding to the pixel area; an emission layer on the first electrode; and a second electrode on the emission layer.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate aspects of the disclosure and together with the description serve to explain principles of the disclosure. In the drawings:

FIG. 1 illustrates an example system configuration of a display device according to aspects of the present disclosure;

FIG. 2 is an example plan view taken along line A-A′ of the display device shown in FIG. 1 according to aspects of the present disclosure;

FIG. 3 is an example cross-sectional view taken along line B-B′ of FIG. 2;

FIG. 4 illustrates example light traveling paths in the display device of FIG. 3 according to aspects of the present disclosure;

FIG. 5 illustrates example light traveling paths in a display device;

FIG. 6A illustrates an example arrangement in which a light scattering portion is disposed on an overcoat layer;

FIG. 6B illustrates an example arrangement in which a light scattering portion is disposed under an overcoat layer;

FIG. 7 is an example table illustrating luminance improvement rates and luminance half-viewable angles according to weights of the light scattering portion included in the overcoat layer of FIG. 6A and of FIG. 6B;

FIG. 8 is an example plot illustrating luminance improvement rates according to weights of the light scattering portion included in the overcoat layer of FIG. 6A and of FIG. 6B;

FIG. 9 is an example table illustrating light efficiency and half-viewable angles according to locations of a light scattering portion;

FIGS. 10 to 13 are example cross-sectional views of the display device according to aspects of the present disclosure;

FIG. 14 is another example cross-sectional view of the display device according to aspects of the present disclosure;

FIG. 15 is another example plan view of the display device according to aspects of the present disclosure;

FIG. 16 is an example cross-sectional view taken along line C-C′ of FIG. 15; and

FIG. 17 illustrates example light traveling paths in the display device of FIG. 16.

### DETAILED DESCRIPTION

Reference will now be made in detail to embodiments of the present disclosure, examples of which may be illustrated in the accompanying drawings.

In the following description, the structures, embodiments, implementations, methods and operations described herein are not limited to the specific example or examples set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements may be added unless the term, such as “only,” is used. An element described in the singular form is intended to include a plurality of elements, and vice versa, unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to,” “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc. each other via a fourth element. Here, the second element may be included in at least one of two or more elements that “are connected or coupled to,” “contact or overlap,” etc. each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

Hereinafter, with reference to the accompanying drawings, various embodiments of the present disclosure will be described in detail.

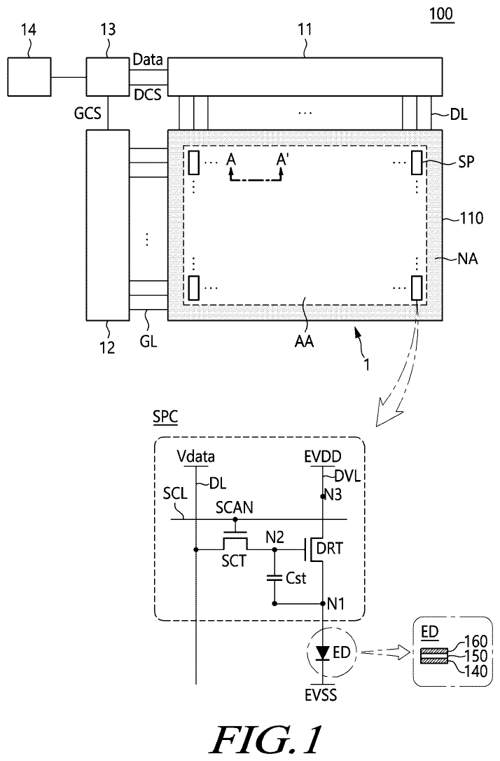

FIG. 1 illustrates an example system configuration of a display device 100 according to aspects of the present disclosure;

As illustrated in FIG. 1, in one or more aspects, a display driving system of the display device 100 may include a display panel 1 and a display driving circuit for driving the display panel 1.

The display panel 1 may include a display area AA allowing an image to be displayed and a non-display area NA where an image is not displayed. The display panel 1 may include a base substrate 110 and a plurality of subpixels SP disposed on the base substrate 110 to display an image.

The display panel 1 may include a plurality of signal lines disposed on the base substrate 110. For example, the plurality of signal lines may include data lines DL, gate lines GL, driving voltage lines DVL, and the like.

Each of the plurality of data lines DL may be disposed such that each data line DL extends in a first direction (e.g., a column direction or a row direction), and each of the plurality of gate lines GL may be disposed such that each gate line GL extends in a direction intersecting the first direction.

The display driving circuit may include a data driving circuit 11 and a gate driving circuit 12, and may further include a controller 13 for controlling the data driving circuit 11 and the gate driving circuit 12.

The data driving circuit 11 can output data signals (which may also referred to as data voltages) corresponding to image signals to a plurality of data lines DL. The gate driving circuit 12 can generate gate signals and output the generates gate signals to a plurality of gate lines GL.

The controller 13 can convert image data inputted from an external device or system, such as a host system 14, to a data signal form interpretable by the data driving circuit 11 and supply the converted image data to the data driving circuit 11.

The data drive circuit 11 may include one or more source driver integrated circuits. For example, each source driver integrated circuit may be connected to the display panel 1 by a tape-automated-bonding (TAB) technique, or connected to a conductive pad, such as a bonding pad of the display panel 1, by a chip-on-glass (COG) technique or a chip-on-panel (COP) technique, or connected to the display panel 1 by a chip-on-film (COF) technique. However, embodiments of the present disclosure are not limited thereto.

For example, the gate driving circuit 12 may be connected to the display panel 1 by the tape-automated-bonding (TAB) technique, or connected to a conductive pad, such as a bonding pad of the display panel 1, by the chip-on-glass (COG) technique or the chip-on-panel (COP) technique, or connected to the display panel 1 by the chip-on-film (COF) technique, or disposed in the non-display area NA of the display panel 1 by a gate-in-panel (GIP) technique.

As illustrated in FIG. 1, in one or more aspects, each of a plurality of subpixels SP included in the display device 100 may include a light emitting element ED, and a pixel driving circuit SPC for driving the light emitting element ED. The pixel driving circuit SPC may include a driving transistor DRT, a scan transistor SCT, a storage capacitor Cst, and the like.

The driving transistor DRT can drive the light emitting element ED by controlling current flowing into the light emitting element ED. The scan transistor SCT can pass a data voltage Vdata to a second node N2, which is the gate node of the driving transistor DRT. The storage capacitor Cst may be configured to maintain voltage at a certain level for a certain period of time.

The light emitting element ED may include a first electrode 140, a second electrode 160, and an emission layer 150 located between the first electrode 140 and the second electrode 160. The first electrode 140 may be a pixel electrode included in a corresponding light emitting element ED of each subpixel SP, and may be electrically connected to a first node N1 of the driving transistor DRT. The second electrode 160 may be a common electrode commonly included in corresponding two or more light emitting elements ED of all or two or more of a plurality of subpixels SP included in the display panel 1, and a base voltage EVSS may be applied to the second electrode 160.

In some aspects, the light emitting element ED may be an organic light emitting diode (OLED), an inorganic material-based light emitting diode (LED), or a quantum dot light emitting element, which is a self-emissive semiconductor crystal.

The driving transistor DRT may be a transistor for driving the light emitting element ED, and include the first node N1, the second node N2, and a third node N3. The first node N1 may be the source node (source electrode) or the drain node (drain electrode) of the driving transistor DRT, and be electrically connected to the first electrode of the light emitting element ED. The second node N2 may be the gate node of the driving transistor DRT, and may be electrically connected to the source or drain node of the scan transistor SCT. The third node N3 may be the drain node (drain electrode) or the source node (source electrode) of the driving transistor DRT, and may be electrically connected to a driving voltage line DVL for supplying a driving voltage EVDD. Hereinafter, for merely convenience of explanation, discussions may be provided based on examples where the first, second, and third nodes (N1, N2, and N3) of the driving transistor DT are source, gate, and drain nodes, respectively. However, embodiments of the present disclosure are not limited thereto.

The scan transistor SCT can control a connection between a data line DL and the second node N2 of the driving transistor DRT. For example, the scan transistor SCT can control a connection between a corresponding data line DL among a plurality of data lines DL and the second node N2 of the driving transistor DRT according to a scan signal SCAN delivered through a corresponding scan line SCL among a plurality of scan lines SCL, which are one type of gate line. The storage capacitor Cst may be configured between the first node N1 and the second node N2 of the driving transistor DRT.

The structure of the subpixel SP illustrated in FIG. 1 is merely an example for explanation. For example, the subpixel SP may further include one or more transistors or one or more capacitors. For example, each of a plurality of subpixels may have the same structure, or one or more of the plurality of subpixels may have a different structure from one or more other subpixels. The driving transistor DRT and the scan transistor SCT may be n-type transistors or p-type transistors.

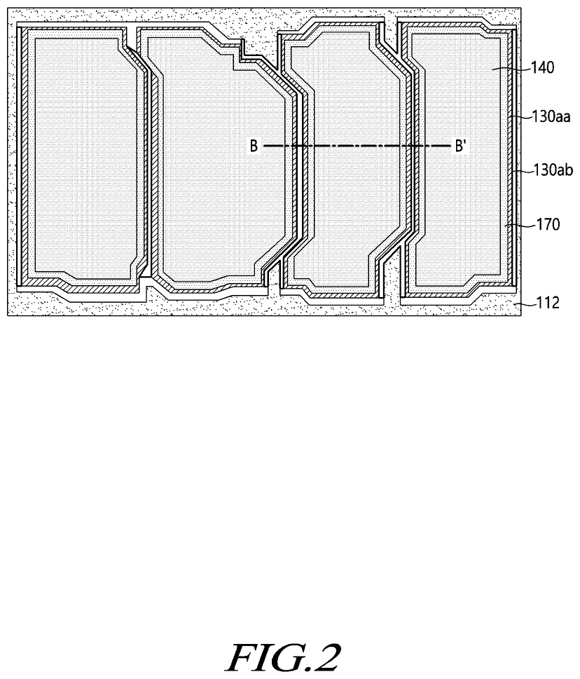

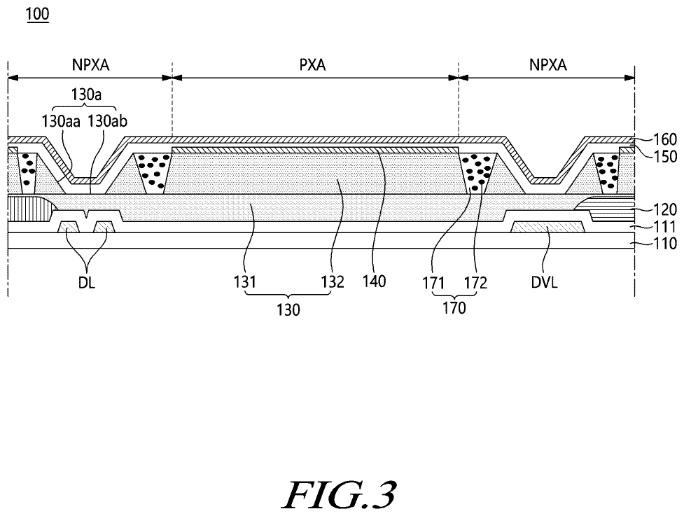

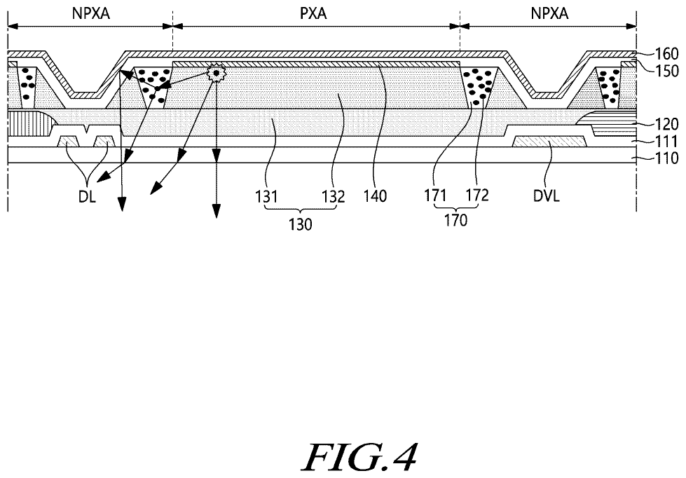

FIG. 2 is an example plan view taken along line A-A′ of the display device 100 shown in FIG. 1 according to aspects of the present disclosure. FIG. 3 is an example cross-sectional view taken along line B-B′ of FIG. 2. FIG. 4 illustrates example light traveling paths in the display device 100 of FIG. 3 according to aspects of the present disclosure.

With reference to FIGS. 2 to 4, in one or more aspects, the display device 100 may include a base substrate 110, at least one color filter 120, an overcoat layer 130, a first electrode 140, an emission layer 150, and a second electrode 160.

The base substrate 110 may serve to support various components of the display device 100, and may include an insulating material, such as a glass substrate, a plastic substrate, or the like. The base substrate 110 may include a pixel area PXA in which circuit elements included in at least one subpixel SP and at least one light emitting element ED are disposed, and a non-pixel area NPXA disposed around the pixel area PXA (e.g., outside of the pixel area PXA) The non-pixel area NPXA may include a boundary between adjacent subpixels SP and/or a non-display area NA.

Various signal lines may be disposed in the non-pixel area NPXA of the base substrate 110. For example, at least one data line DL may be disposed on a first side of the first electrode 140, and a driving voltage line DVL may be disposed on a second opposing side of the first electrode 140. The at least one data line DL and the driving voltage line DVL may be protected by a buffer layer 111 and a data bank 112.

A plurality of color filters 120 may be disposed on the buffer layer 111 such that the plurality of color filters 120 are spaced apart from each other. Each of the plurality of color filters 120 may be configured to correspond to the color of a corresponding subpixel SP. For example, when each pixel includes a red subpixel, a green subpixel, and a blue subpixel, the color filters 120 may correspondingly include red color filters 120, green color filters 120, and blue color filters 120.

The overcoat layer 130 may be a planarization layer for alleviating a difference in height between layers or structures located under the overcoat layer 130, and may be disposed on the base substrate 110. For example, the overcoat layer 130 may have a groove 130a recessed in an area corresponding to the non-pixel area NPXA, and may include an organic material, such as polyimide, benzocyclobutene series resin, acrylate, or the like.

The overcoat layer 130 may have a refractive index of 1.4 to 1.6 and may include a first layer 131 and a second layer 132. The first layer 131 may be disposed on the base substrate 110, and can alleviate a difference in height between layers or structures located under the overcoat layer 130.

The second layer 132 may be disposed on the first layer 131, and the groove 130a of the overcoat layer 130 may be a hole or opening formed at a portion of the second layer 132. For example, the groove 130a may be disposed in an area corresponding to the non-pixel area NPXA, and both side surfaces of the groove 130a may be configured with inclined surfaces 130aa, which are formed such that a width between the inclined surfaces becomes smaller in a downward direction. For example, the sides of the groove 130a may be configured with the inclined surfaces 130aa, and the bottom of the groove 130a may be configured with a bottom surface 130ab contacting the top of the first layer 131. For example, the groove 130a may be configured in a “¬” shape. For example, the groove 130a may define a flat bottom V shape. Further, the inclined surface 130aa may be configured to have an inclination of 30 to 70°.

The first electrode 140 may be an anode, and each subpixel SP may include a respective first electrode 140. For example, each of a plurality of first electrode 140 may be disposed on a portion of the overcoat layer 130 corresponding to a pixel area PXA in which a corresponding subpixel SP among a plurality of subpixels SP is disposed. The first electrode 140 may be absent in the groove 130a.

The first electrode 140 may be configured with a transparent electrode, such as indium tin oxide (ITO), indium zinc oxide (IZO), and/or the like, or an opaque electrode, such as aluminum (Al), copper (Cu), nickel (Ni), and/or the like. For example, the first electrode 140 may have a structure in which at least one transparent electrode and at least one opaque electrode are stacked.

The emission layer 150 may be disposed on the groove 130a and the first electrode 140. For example, the emission layer 150 may be disposed in the pixel area PXA and the non-pixel area NPXA, and may be disposed in the groove 130a in the non-pixel area NPXA.

For example, the emission layer 150 may be an organic compound layer, and include a hole injection layer (HIL), a hole transport layer (HTL), an active layer (EML), an electron transport layer (ETL), an electron injection layer (EIL), and the like. The emission layer 150 may be disposed in the pixel area PXA and the non-pixel area NPXA.

The second electrode 160 may be a cathode, and may be disposed on the emission layer 150. For example, the second electrode 160 may be disposed in the pixel area PXA and the non-pixel area NPXA, and may be disposed in the groove 130a in the non-pixel area NPXA.

In one or more aspects. the second electrode 160 may be used as a reflective electrode, and may include a reflective material. To serve as a reflective electrode, the second electrode 160 may be configured with an opaque electrode, such as aluminum (Al), copper (Cu), nickel (Ni), and/or the like, with good reflectivity. For example, the second electrode 160 may have a structure in which a transparent electrode, such as indium tin oxide (ITO), indium zinc oxide (IZO), and/or the like, and an opaque electrode are stacked.

According to the examples described above, as the second electrode 160 used as a reflective electrode is disposed in the groove 130a of the overcoat layer 130, the luminance of the display device 100 can be improved by causing wave guide mode light to be extracted to the outside.

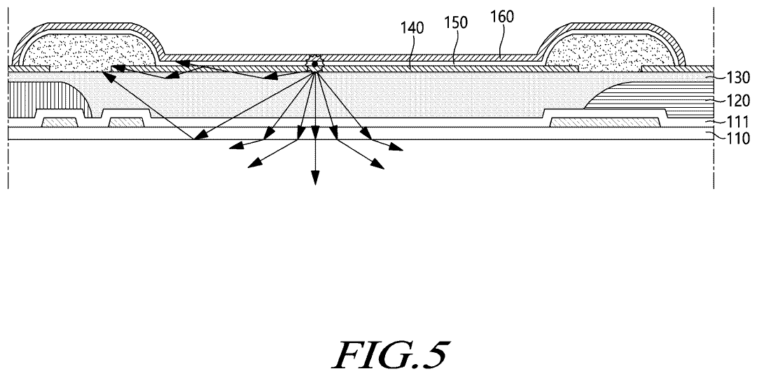

FIG. 5 illustrates example traveling paths of light emitted from a light emitting element of a display panel 1. The wave guide mode is defined with reference to FIG. 5.

As shown in FIG. 5, some of light generated in an emission layer 150 may fail to exit the display panel 1 due to a difference in refractive index between the emission layer 150 and a layer contacting the emission layer 150, and be totally reflected. The totally reflected light, which has failed to exit the display panel 1, may be trapped inside of one or more layers or structures of the display panel 1. In the situation where some of the generated light is totally reflected in the emission layer 150, a loss mode caused when a thickness (d) of the emission layer 150 is similar to a wavelength (λ) of the totally reflected light (e.g., d≅λ; thickness is approximately equal to wavelength) may be referred to as a wave guide mode. The wave guide mode may be a cause of decreasing light extraction efficiency because light totally reflected at an interface between the emission layer 150 and a layer contacting the emission layer 150, for example, an overcoat layer 130, may be disappear after traveling sidewards (e.g., leftwards or rightwards).

To address the wave guide mode issue, in one or more aspects, the display device 100 may have the structure of disposing the second electrode 160 in the groove 130a of the overcoat layer 130 as illustrated in FIG. 4. For example, as shown in FIG. 4, even if light travels sidewards (e.g., the light travels in the wave guide mode), the light may be reflected again by the second electrode 160 disposed in the groove 130a, and be caused to exit the display device 100.

By applying this configuration, light extraction efficiency can be improved, and in turn, the display device 100 can be operated with low power based on the improved light extraction efficiency.

In one or more aspects, the overcoat layer 130 may further include a light scattering portion 170 for scattering wave guide mode light. For example, the light scattering portion 170 may be disposed between the first electrode 140 and the groove 130a, and be disposed such that the light scattering portion 170 does not overlap with the first electrode 140.

The light scattering portion 170 may include transparent resin 171 including light scattering particles 172. The transparent resin 171 may include acrylic, urethane, epoxy, vinyl, polyester, and/or polyamide resins that have excellent light transmittance and easy viscosity control. The light scattering particles 172 included in the transparent resin 171 may have a size of micro (μm) or less and may include TiO₂ or SiO₂.

The transparent resin 171 and the light scattering particles 172 may have different refractive indices. For example, the refractive index of the transparent resin 171 may be 1.4 to 1.6, and the refractive index of the light scattering particles 172 may be 2.3 to 2.5.

Due to this difference in refractive index, when light reflected at an interface between the emission layer 150 and the base substrate 110 reaches the light scattering portion 170, the reflected light can be scattered by the light scattering portion 170 and be caused to travel in various light paths. By disposing the light scattering portion 170, as the reflected light is caused to travel in various light paths, the display device 100 can provide improved front, left, and/or right viewing angles.

Meanwhile, even if light reflected at an interface between the emission layer 150 and the overcoat layer 130 passes through the light scattering portion 170 and travels sidewards, the light can be reflected by the second electrode 160 located on at least one of sides of the light scattering portion 170, and be cause to exit the display panel 1. Thus, the display device 100 can provide improved light extraction efficiency.

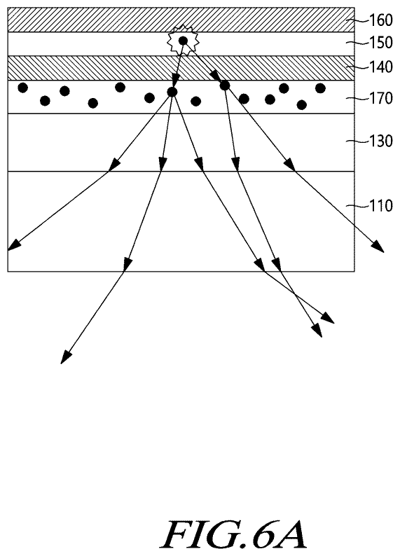

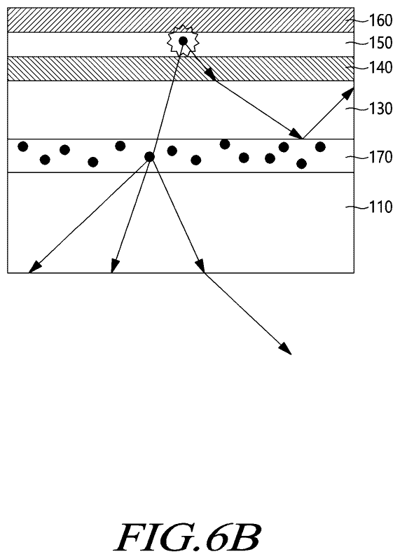

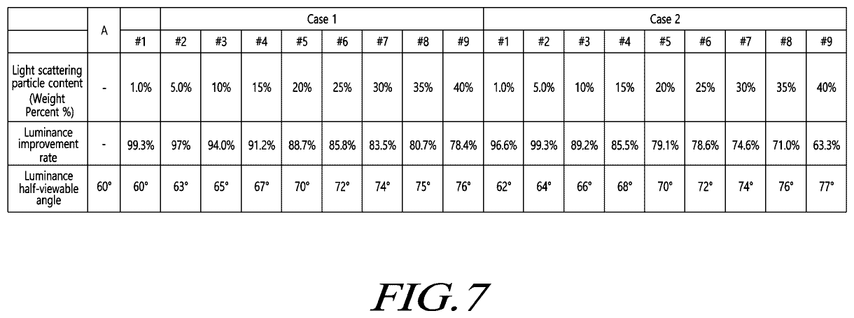

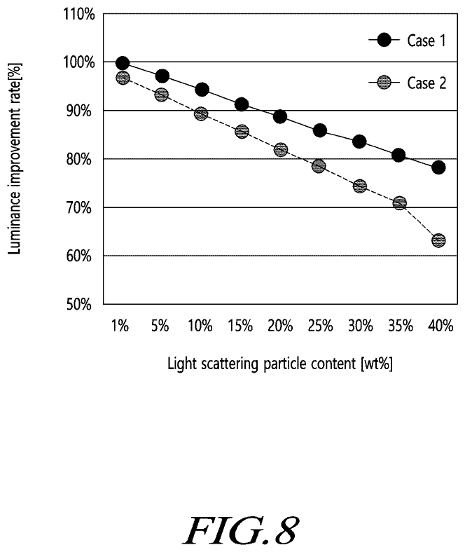

FIG. 6A illustrates an example arrangement in which the light scattering portion 170 is disposed on the overcoat layer 130. FIG. 6B illustrates an example arrangement in which the light scattering portion 170 is disposed under the overcoat layer 130. FIG. 7 is an example table illustrating luminance improvement rates and luminance half-viewable angles according to weights of the light scattering portion 170 included in the overcoat layer 130 in the example arrangement of FIG. 6A and the example arrangement of FIG. 6B. FIG. 8 is an example plot illustrating luminance improvement rates according to weights of the light scattering portion 170 included in the overcoat layer 130 in the example arrangement of FIG. 6A and the example arrangement of FIG. 6B.

For example, the thickness of the light scattering portion 170 in the example arrangement of FIG. 6A and the example arrangement in FIG. 6B may be 1 μm, the refractive index of the transparent resin 171 included in the light scattering portion 170 may be 1.53, and the refractive index of the light scattering particles 172 may be 2.46. Further, the reflectance of lines may be 32% and an average aperture ratio may be 37%. It should be noted that respective structures (A) of FIGS. 6A and 6B have similar structures except that the respective light scattering portions 170 are differently located and configured.

With reference to FIGS. 6A to 8, it can be seen that the arrangement of FIG. 6A, in which the light scattering portion 170 is disposed adjacent to the emission layer 150, provides more luminance improvement. This is because as the light scattering portion 170 is located closer to the emission layer 150, more wave guide mode light can be incident to the light scattering portion 170 just before being disappeared, and be scattered. Therefore, in the example where the overcoat layer 130 includes the first layer 131 and the second layer 132 as in configurations of FIGS. 3 and 4, the light scattering portion 170 may be preferably disposed on the second layer 132.

In addition, it can be seen that: an example where the weight of the light scattering portion 170 included in the overcoat layer 130 is 1 to 20% provides best luminance improvement; and as the weight of the light scattering portion 170 increases, a corresponding luminance half-viewable angle also increases proportionally. Here, the half-viewable angle may mean a viewing angle at which luminance is 50% when luminance at the center is 100%.

Based on these results, the display device 100 can be provided with desired luminance and viewing angles by appropriately adjusting the weight of the light scattering portion 170 included in the overcoat layer 130.

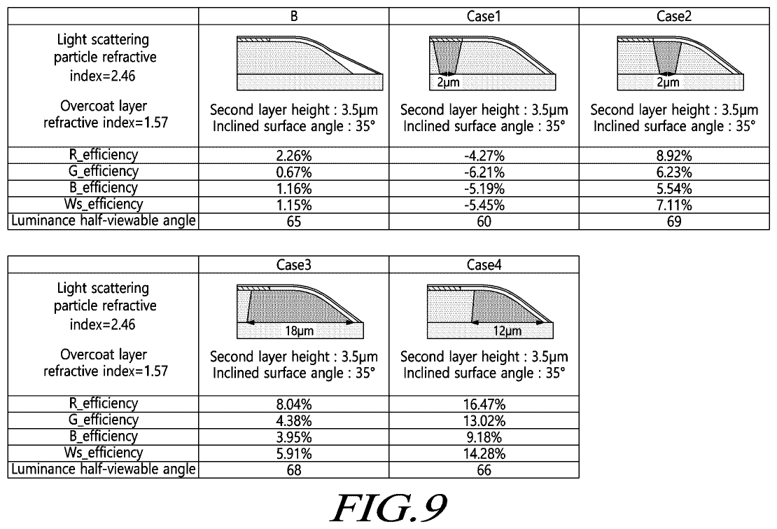

FIG. 9 is an example table illustrating light efficiency and half-viewable angles according to locations of the light scattering portion 170 as compared to a reference structure (B).

For example, in Case 1 of FIG. 9, the light scattering portion 170 may be disposed under the first electrode 140 and overlap with the first electrode 140. In Case 2 of FIG. 9, the light scattering portion 170 may be disposed between a lower end of the first electrode 140 and the inclined surface 130aa of the groove 130a and not overlap with the first electrode 140. In Case 3 of FIG. 9, the light scattering portion 170 may be disposed such that it overlaps with a portion of the first electrode 140. In Case 4 of FIG. 9, the light scattering portion 170 may be disposed spaced apart from the first electrode 140 not to overlap with the first electrode 140. In furtherance to Case 4, the light scattering portion 170 may be disposed between the first electrode 140 and the inclined surface 130aa of the groove 130a. Further, it should be noted that the reference structure (B) and the structures of Case 1 to Case 4 have similar structures except that the respective light scattering portions 170 of Case 1 to Case 4 are provided and respectively differently configured.

The example arrangement of Case 1 of FIG. 9, in which the light scattering portion 170 is disposed under the first electrode 140 and overlaps with the first electrode 140, produces poor light efficiency and half-viewable angles. Further, the example arrangement of Case 2 of FIG. 9, in which the light scattering portion 170 is disposed between the first electrode 140 and the inclined surface 130aa of the groove 130a, produces good light efficiency and half-viewable angle. In particular, it can be seen that Case 4, in which the light scattering portion 170 is disposed up to the inclined surface 130aa of the groove 130a without overlapping with the first electrode 140, produces the best light efficiency.

In view of these results, the display device 100 can be provided with desired luminance and viewing angle by appropriately disposing the light scattering portion 170 included in the overcoat layer 130.

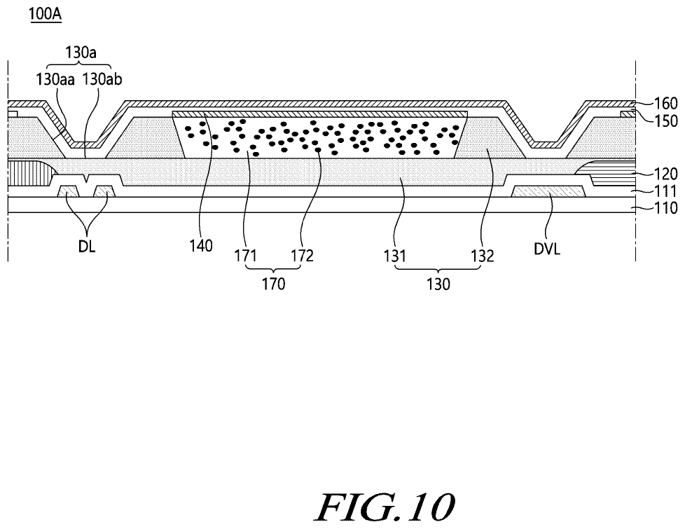

FIG. 10 is a cross-sectional view of one example 100A of the display device 100 according to aspects of the present disclosure. The example of FIG. 10 will be explained with reference to differences from the previously described examples.

In FIG. 10, the light scattering portion 170 of the display device 100A may be disposed such that it overlaps with the first electrode 140 in the second layer 132 of the overcoat layer 130. For example, the light scattering portion 170 may correspond to a length of the first electrode 140 such that both opposing side ends of the light scattering portion 170 align with both side ends of the first electrode 140, respectively. In this example, a width between both side surfaces of the light scattering portion 170 may become smaller in a downward direction.

Thus, the light scattering portion 170 may have inclined surfaces, which are inclined at a certain angle to the top or bottom surface of the light scattering portion 170. As in this example, when the side surfaces of the light scattering portion 170 are configured with the inclined surfaces, light present on (or adjacent to), or passing through, the first electrode 140 can be scattered at various angles at an interface between the light scattering portion 170 and the first electrode 140. Thereby, the display device 100A with this configuration can provide improved front, left, and right viewing angles.

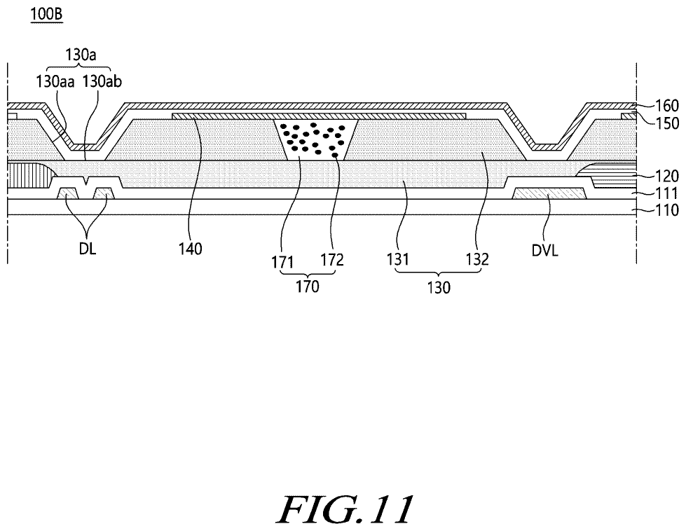

FIG. 11 is a cross-sectional view of another example 100B of the display device 100 according to aspects of the present disclosure. The example of FIG. 11 will be explained with reference to differences from the previously described examples.

In accordance with FIG. 11, the light scattering portion 170 of the display device 100B may be disposed such that it overlaps with the first electrode 140 in the second layer 132 of the overcoat layer 130. For example, the light scattering portion 170 may have a length shorter than the first electrode 140, and face a central portion of the first electrode 140. In this example, a width between both side surfaces of the light scattering portion 170 may become smaller in a downward direction.

Thus, because the light scattering portion 170 has inclined surfaces, which are inclined at a certain angle to the top or bottom surface of the light scattering portion 170, light totally reflected at an interface between the emission layer 150 and the overcoat layer 130 can be scattered in more various paths, and thereby, the display device 100B with this configuration can provide improved front, left, and right viewing angles.

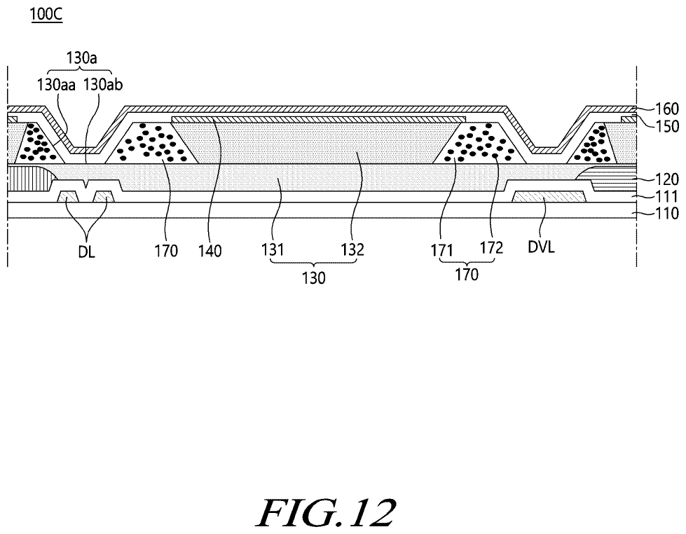

FIG. 12 is a cross-sectional view of another example 100C of the display device 100 according to aspects of the present disclosure. The example of FIG. 12 will be explained with reference to differences from the previously described examples.

As shown in FIG. 12, the light scattering portion 170 of the display device 100C may be disposed such that it overlaps with a portion of the first electrode 140 and a portion of the emission layer 150 disposed in the groove 130a in the second layer 132 of the overcoat layer 130. For example, the light scattering portion 170 may be disposed such that one of side portions of the light scattering portion 170 overlaps with a side portion of the first electrode 140, and the other of the side portions is disposed along an inclined surface 130aa of the groove 130a and overlaps with the emission layer 150. In this example, a width between both inclined surfaces of the light scattering portion 170 may become smaller in an upward direction.

Thus, the light scattering portion 170 may have inclined surfaces, which are inclined at a certain angle to the top or bottom surface of the light scattering portion 170. For example, the inclined surfaces of the light scattering portion 170 may be formed at an angle corresponding to the inclined surface 130aa of the groove 130a.

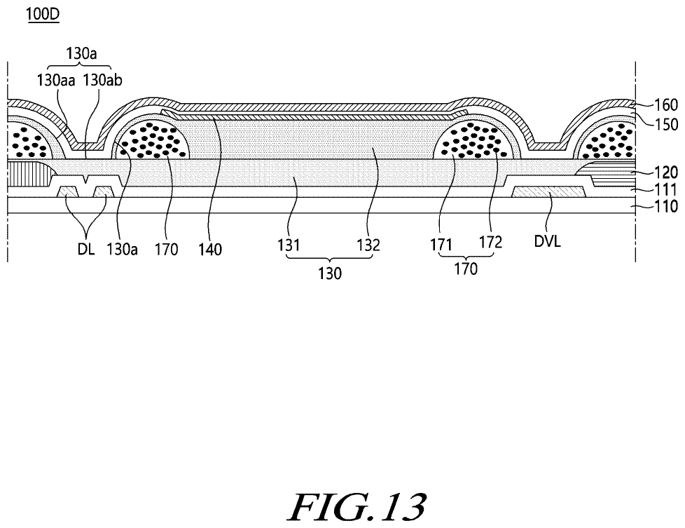

FIG. 13 is a cross-sectional view of another example 100D of the display device 100 according to aspects of the present disclosure. The example of FIG. 13 with be explained with reference to differences from the previously described examples.

As shown in FIG. 13, the light scattering portion 170 of the display device 100D may be disposed such that it overlaps with a portion of the first electrode 140 and a portion of the emission layer 150 disposed in the groove 130a in the second layer 132 of the overcoat layer 130. For example, the light scattering portion 170 may be disposed between the first electrode 140 and the groove 130a, and an upper portion of the light scattering portion 170 may have a dome shape. For example, the light scattering portion 170 may have a hemispherical shape.

In the example where the upper portion of the light scattering portion 170 has a dome shape, the second electrode 160 disposed on the light scattering portion 170 may also have a curved surface to match the shape of the light scattering portion 170. In this example, because the second electrode 160 can be disposed so that an angle of a bent area between the pixel area PXA and the non-pixel area NPXA can become smaller than that of the straight shape, thereby, the display device 100D with this configuration can provide an advantage of preventing oxygen and moisture penetration caused by disconnection.

Both ends of the first electrode 140 may have an arc shape corresponding to the shape of the light scattering portion 170, and may overlap with a portion of the light scattering portion 170. In the example where both ends of the first electrode 140 are disposed along the curved surface of the light scattering portion 170, wave guide mode light traveling toward any side of the first electrode 140 may be caused to frontally travel by the curved surface of the second electrode 160. Thus, the front viewing angle can be improved even when the curved surface (or a portion corresponding to, or adjacent to, the curved surface) of the second electrode 160 is not formed at an angle of 45° or more to a flat portion of the second electrode 160.

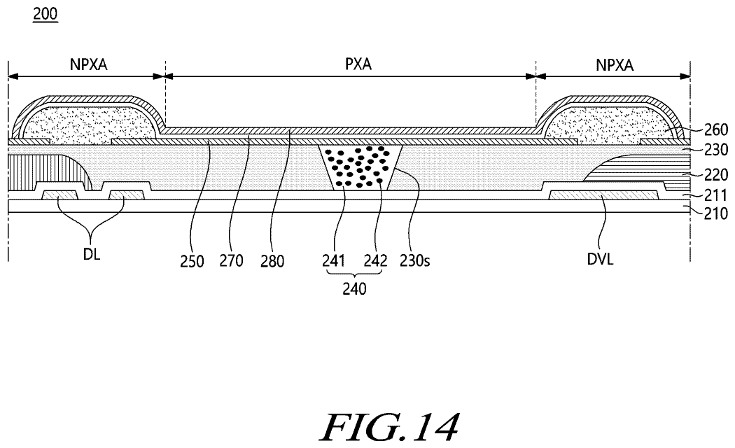

FIG. 14 is another example cross-sectional view of the display device according to aspects of the present disclosure.

As shown in FIG. 14, in one or more aspects, an example 200 of the display device 100 may include a base substrate 210, at least one color filter 220, an overcoat layer 230, a light scattering portion 240, a first electrode 250, a bank layer 260, an emission layer 270, and a second electrode 280.

The base substrate 210 may be configured to support various components of the display device 200, and include a pixel area PXA where one or more subpixels SP are disposed and a non-pixel area NPXA located outside of the pixel area PXA. Various signal lines may be disposed in the non-pixel area NPXA of the base substrate 210. For example, at least one data line DL may be disposed on a first side of the first electrode 250, and a driving voltage line DVL may be disposed on a second opposing side of the first electrode 250. The at least one data line DL and the driving voltage line DVL may be protected by a buffer layer 211. For example, the buffer layer 211 may include silicon oxide (SiOx), silicon nitride (SiNx), or a combination thereof.

A plurality of color filters 220 may be disposed on the buffer layer 211 such that the plurality of color filters 220 are spaced apart from each other. Each of the plurality of color filters 220 may be configured to correspond to the color of a corresponding subpixel SP. For example, when each pixel includes a red subpixel, a green subpixel, and a blue subpixel, the color filters 220 may correspondingly include red color filters 220, green color filters 220, and blue color filters 220.

The overcoat layer 230 may be a planarization layer for alleviating a difference in height between layers or structures located under the overcoat layer 230, and may be disposed on the base substrate 210. For example, the overcoat layer 230 may have a refractive index of 1.4 to 1.6, and include a depressed space 230s (or recessed space, or hole) disposed in an area corresponding to the pixel area PXA or the non-pixel area NPXA.

The light scattering portion 240 may serve to scatter wave guide mode light and be disposed in the depressed space 230s. For example, the light scattering portion 240 may be formed such that it corresponds to the shape of the depressed space 230s. Accordingly, a width of both side surfaces of the light scattering portion 240 may also become smaller in a downward direction.

The light scattering portion 240 may include transparent resin 241 including light scattering particles 242.

The transparent resin 241 may include acrylic, urethane, epoxy, vinyl, polyester, and/or polyamide resins that have excellent light transmittance and easy viscosity control. The light scattering particles 242 included in the transparent resin 241 may have a size of micro (μm) or less and may include TiO₂ or SiO₂.

The transparent resin 241 and the light scattering particles 242 may have different refractive indices. For example, the refractive index of the transparent resin 241 may be 1.4 to 1.6, and the refractive index of the light scattering particles 242 may be 2.3 to 2.5.

Due to this difference in refractive index, when light reflected at an interface between the emission layer 270 and the overcoat layer 230 reaches the light scattering portion 240, the reflected light can be scattered by the light scattering portion 240 and be caused to travel in various light paths. By disposing the light scattering portion 240, as light is caused to travel in various light paths, the display device 200 can provide improved front, left, and/or right viewing angles.

The first electrode 250 may be an anode, and each subpixel SP may include a respective first electrode 250. For example, each of a plurality of first electrode 250 may be disposed on a portion of the overcoat layer 230 corresponding to a pixel area PXA in which a corresponding subpixel SP among a plurality of subpixels SP is disposed.

The first electrode 250 may be configured with a transparent electrode, such as indium tin oxide (ITO), indium zinc oxide (IZO), and/or the like, or an opaque electrode, such as aluminum (Al), copper (Cu), nickel (Ni), and/or the like. For example, the first electrode 250 may have a structure in which at least one transparent electrode and at least one opaque electrode are stacked.

The bank layer 260 may serve to partition one or more pixels and may be disposed on the overcoat layer 230. For example, the bank layer 260 may include an opening for exposing a portion of the first electrode 250, and light can travel through the opening.

The emission layer 270 may be disposed on the bank layer 260 and the first electrode 250. For example, the emission layer 270 may be an organic compound layer, and include a hole injection layer (HIL), a hole transport layer (HTL), an active layer (EML), an electron transport layer (ETL), an electron injection layer (EIL), and the like. The emission layer 270 may be disposed in the pixel area PXA and the non-pixel area NPXA.

The second electrode 280 may be a cathode, and be disposed on the emission layer 270. For example, the second electrode 280 may be provided in the pixel area PXA and the non-pixel area NPXA.

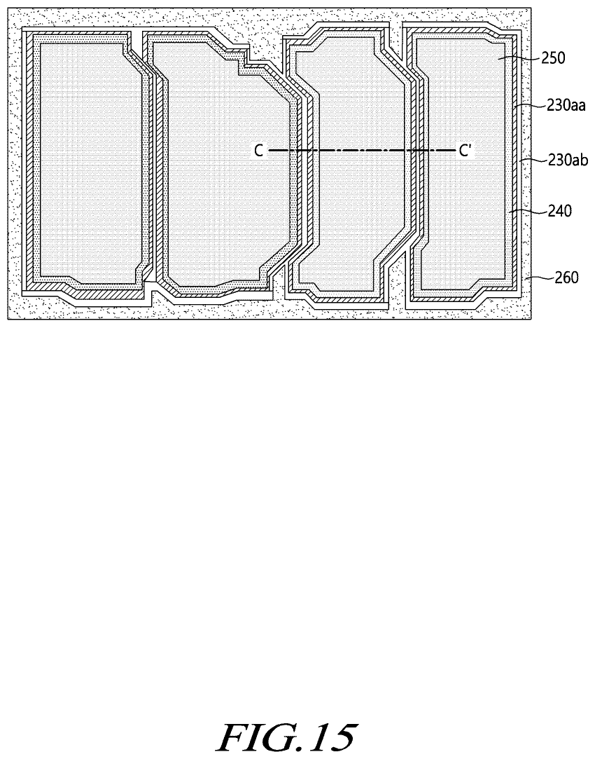

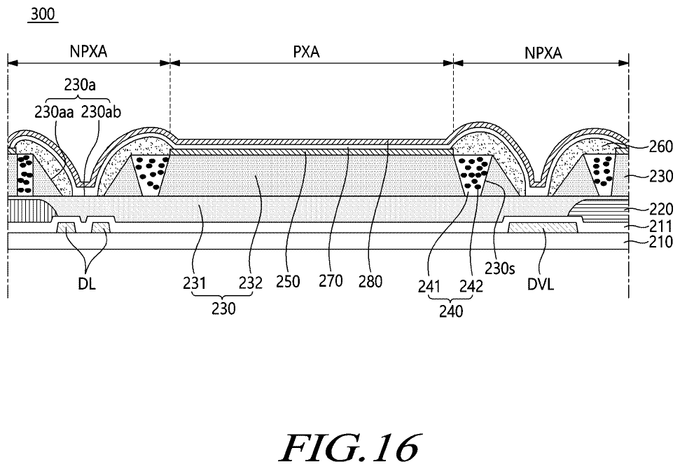

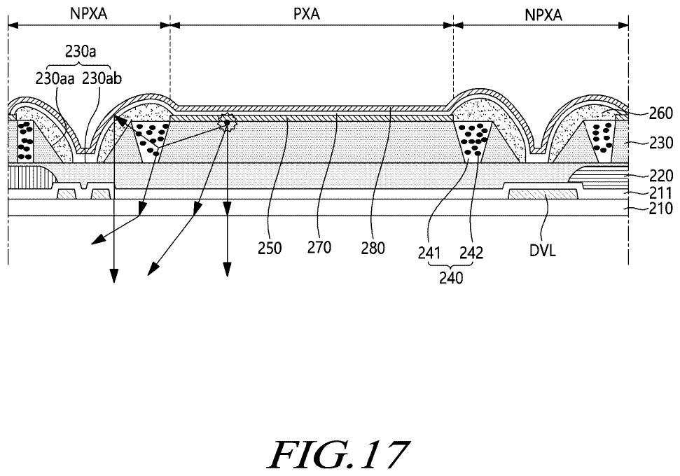

FIG. 15 is the plan view of the display device according to aspects of the present disclosure. FIG. 16 is an example cross-sectional view taken along line C-C′ of FIG. 15. FIG. 17 illustrates example light traveling paths in the display device of FIG. 16. The examples of FIGS. 15 to 17 with be explained with reference to differences from the previously described examples.

With reference to FIGS. 15 to 17, an example 300 of the display device 100 may include the groove 230a recessed in the overcoat layer 230. For example, the overcoat layer 230 may have a refractive index of 1.4 to 1.6 and may include a first layer 231 and a second layer 232.

The first layer 231 may be disposed on the buffer layer 211, and can alleviate a difference in height between layers or structures located under the overcoat layer 230.

The second layer 232 may be disposed on the first layer 231, and the depressed space 230s and the groove 230a may be disposed in the non-pixel area NPXA. For example, the depressed space 230s may be disposed closer to the pixel area PXA than the groove 230a. The groove 230a disposed in the second layer 232 may be recessed in an area corresponding to the non-pixel area NPXA, and both side surfaces of the groove 230a may be configured with inclined surfaces 230aa, which are formed such that a width between the inclined surfaces becomes smaller in a downward direction. For example, the sides of the groove 230a may be configured with the inclined surfaces 230aa, and the bottom of the groove 230a may be configured with a bottom surface 230ab contacting the top of the first layer 231.

For example, the bank layer 260, the emission layer 270, and the second electrode 280 may be disposed in the groove 230a. The bank layer 260 may serve to partition one or more pixels, and include an opening configured to expose a portion of the first electrode 250 and cause light to be travel through the opening.

The bank layer 260 may be disposed in the groove 230a of the overcoat layer 230. For example, the bank layer 260 may have lower portions separated from each other with an intervening portion, which may correspond to a portion or space between both the inclined surfaces 230aa of the groove 230a, for example, a portion of the bottom surface 230ab. By applying this structure, the bank layer 260 may cover from at least one of the inclined surfaces 230aa of the groove 230a to at least one of ends of the first electrode 250, but may not cover the portion of the bottom surface 230ab of the groove 230a. Accordingly, because the bank layer 260 is not present in the bottom of the emission layer 270 disposed in the groove 230a, the size of the display device 300 can be minimized.

For example, the light scattering portion 240 disposed in the overcoat layer 230 may not overlap with the first electrode 250. For example, the light scattering portion 240 may be disposed between the first electrode 250 and the groove 230a in the non-pixel area NPXA, and an upper portion of the light scattering portion 240 may be shielded by the bank layer 260.

The light scattering portion 240 may be disposed in the depressed space 230s disposed in the second layer 232 of the overcoat layer 230. For example, both side surfaces of the light scattering portion 240 may be configured with inclined surfaces, which are formed such that a width between the inclined surfaces becomes smaller in a downward direction.

By applying the foregoing configurations, as the light scattering portion 240 is disposed in the overcoat layer 230, when light reflected at an interface of the overcoat layer 230 reaches the light scattering portion 240, the light can be scattered in various paths by the light scattering portion 240. Thus, because the reflected light is caused to travel in various paths by the light scattering portion 240 without being disappeared in the wave guide mode, light efficiency can be improved and front, left, and right viewing angles can be improved.

Further, even if light reflected at an interface between the emission layer 270 and the overcoat layer 230 passes through the light scattering portion 240 and travels sidewards, the light can be reflected by the second electrode 280 located on the at least one side and top of the light scattering portion 240, and be cause to exit the display 300. Thus, the display device 300 can provide improved light extraction efficiency.

According to one or more aspects of the present disclosure, a display device may be provided that is capable of improving light efficiency without employing a micro lens array (MLA) structure by including a light scattering portion for scattering wave guide mode light so that the scattered light can exit the display device through various paths.

According to one or more aspects of the present disclosure, a display device may be provided that is capable of improving light efficiency without employing a micro lens array (MLA) structure, reducing a ratio of reflected light to light emitted from a light source, and correcting a black image defect.

According to one or more aspects of the present disclosure, a display device may be provided that has improved front, left, and right viewing angles by including a light scattering portion for scattering light in a wave guide mode in which the light is totally reflected at an interface between an emission layer and an insulating layer, such as an overcoat layer, or the like, and then travels sidewards (e.g., leftwards or rightwards) (which may referred to as “wave guide mode light”), and thereby, causing the scattered light to travel in various optical paths.

According to one or more aspects of the present disclosure, a display device may be provided that has improved luminance by disposing a second electrode, which is used as a reflective electrode, in a groove of an overcoat layer, and causing wave guide mode light, which is totally reflected at an interface between an emission layer and an insulating layer, such as an overcoat layer, or the like, and then travels sidewards (e.g., leftwards or rightwards), to be reflected again by the second electrode and then to travel to the outside.

According to one or more aspects of the present disclosure, a display device may be provided that is capable of being operated with low power as light extraction efficiency is improved by a light scattering portion and a second electrode disposed in an overcoat layer.

The embodiments described above will be briefly described as follows.

According to aspects of the present disclosure, a display device may be provided that comprises a base substrate including a pixel area and a non-pixel area; an overcoat layer on the base substrate, the overcoat layer including a groove at an area corresponding to the non-pixel area; a first electrode on the overcoat layer at an area corresponding to the pixel area; an emission layer in the groove and on the first electrode; and a second electrode on the emission layer, the second electrode at an area corresponding to the pixel area and in the groove.

In one or more aspects, side surfaces of the groove may be inclined, and a width of the groove at a bottom of the groove may be less than a width of the groove at a top of the groove.

In one or more aspects, the inclined surfaces of the groove may have an inclination of 30 to 70°.

In one or more aspects, the overcoat layer may include a first layer, and a second layer on the first layer, the groove being disposed in the second layer.

In one or more aspects, the overcoat layer may further include a light scattering portion configured to scatter light from the emission layer.

In one or more aspects, a width of a bottom of the light scattering portion may be equal to or less than a width of a top of the light scattering portion.

In one or more aspects, an upper surface of the light scattering portion may have a dome shape, at least one end of the first electrode has an arc shape corresponding to the dome shape of the light scattering portion, and the at least one end may overlap respective portions of the light scattering portion.

In one or more aspects, the light scattering portion may be between the first electrode and the groove, and the light scattering portion may not overlap the first electrode.

In one or more aspects, the light scattering portion may be under the first electrode, and the light scattering portion may overlap the first electrode.

In one or more aspects, the light scattering portion may overlap the first electrode and may overlap the emission layer in the groove.

In one or more aspects, the light scattering portion may include transparent resin having light scattering particles therein.

In one or more aspects, a refractive index of the transparent resin may be 1.4 to 1.6, and a refractive index of the light scattering particles may be 2.3 to 2.5.

In one or more aspects, a refractive index of the overcoat layer may be 1.4 to 1.6.

According to aspects of the present disclosure, a display device may be provided that comprises a base substrate including a pixel area and a non-pixel area; an overcoat layer on the base substrate, the overcoat layer including a recessed space in an area corresponding to the pixel area or the non-pixel area, wherein a light scattering portion is in the recessed space; a first electrode on the overcoat layer in an area corresponding to the pixel area; an emission layer on the first electrode; and a second electrode on the emission layer.

In one or more aspects, the overcoat layer may include a groove in an area corresponding to the non-pixel area, and the emission layer and the second electrode may be in the groove.

In one or more aspects, side surfaces of the groove are inclined, and a width of the groove at a bottom of the groove is less than a width of the groove at a top of the groove.

In one or more aspects, the display device may further comprise a bank layer in the non-pixel area on the overcoat layer and in the groove, the bank layer including an opening to expose a portion of the first electrode. The bank layer may have lower portions separated from each other with an intervening portion, and the intervening portion may correspond to a portion or space between the inclined side surfaces of the groove. The emission layer may further be on the bank layer.

In one or more aspects, the light scattering portion may include transparent resin having light scattering particles therein.

In one or more aspects, the light scattering portion may be under the first electrode and overlap the first electrode.

In one or more aspects, the light scattering portion may be between the first electrode and the groove, and the light scattering portion may not overlap the first electrode.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a base substrate including a pixel area and a non-pixel area;
an overcoat layer on the base substrate, the overcoat layer including a groove at an area corresponding to the non-pixel area;
a first electrode on the overcoat layer at an area corresponding to the pixel area;
an emission layer in the groove and on the first electrode; and
a second electrode on the emission layer, the second electrode at an area corresponding to the pixel area and in the groove.

2. The display device according to claim 1, wherein side surfaces of the groove are inclined, and a width of the groove at a bottom of the groove is less than a width of the groove at a top of the groove.

3. The display device according to claim 2, wherein the inclined surfaces of the groove have an inclination of 30 to 70°.

4. The display device according to claim 1, wherein the overcoat layer includes a first layer, and a second layer on the first layer, the groove being disposed in the second layer.

5. The display device according to claim 1, wherein the overcoat layer further includes a light scattering portion configured to scatter light from the emission layer.

6. The display device according to claim 5, wherein a width of a bottom of the light scattering portion is equal to or less than a width of a top of the light scattering portion.

7. The display device according to claim 5, wherein an upper surface of the light scattering portion has a dome shape,
wherein at least one end of the first electrode has an arc shape corresponding to the dome shape of the light scattering portion, and
wherein the at least one end overlaps the light scattering portion.

8. The display device according to claim 5, wherein the light scattering portion is between the first electrode and the groove, and wherein the light scattering portion does not overlap the first electrode.

9. The display device according to claim 5, wherein the light scattering portion is under the first electrode and overlaps the first electrode.

10. The display device according to claim 5, wherein the light scattering portion overlaps with the first electrode and overlaps the emission layer in the groove.

11. The display device according to claim 5, wherein the light scattering portion includes transparent resin having light scattering particles therein.

12. The display device according to claim 11, wherein a refractive index of the transparent resin is 1.4 to 1.6, and a refractive index of the light scattering particles is 2.3 to 2.5.

13. The display device according to claim 12, wherein a refractive index of the overcoat layer is 1.4 to 1.6.

14. A display device, comprising:
a base substrate including a pixel area and a non-pixel area;
an overcoat layer on the base substrate, the overcoat layer including a recessed space in an area corresponding to the pixel area or the non-pixel area, wherein a light scattering portion is in the recessed space;
a first electrode on the overcoat layer in an area corresponding to the pixel area;
an emission layer on the first electrode; and
a second electrode on the emission layer.

15. The display device according to claim 14, wherein the overcoat layer includes a groove in an area corresponding to the non-pixel area, and
wherein the emission layer and the second electrode are in the groove.

16. The display device according to claim 15, wherein side surfaces of the groove are inclined, and a width of the groove at a bottom of the groove is less than a width of the groove at a top of the groove.

17. The display device according to claim 16, further comprising a bank layer in the non-pixel area on the overcoat layer and in the groove, the bank layer including an opening to expose a portion of the first electrode,
wherein the bank layer has lower portions separated from each other with an intervening portion, and the intervening portion corresponds to a portion or space between the inclined side surfaces of the groove.

18. The display device according to claim 14, wherein the light scattering portion includes transparent resin having light scattering particles therein.

19. The display device according to claim 14, wherein the light scattering portion is under the first electrode and overlaps the first electrode.

20. The display device according to claim 15, wherein the light scattering portion is between the first electrode and the groove and does not overlap the first electrode.
